(19) United States
(12) Patent Application Publication
(10) Pub. No.: US 2022/0389257 A1
(43) Pub. Date: Dec. 8, 2022

(54) INK BASED ON SILVER NANOPARTICLES

(71) Applicant: GENES'INK, Rousset (FR)

(72) Inventors: Corinne VERSINI, Aix-en-Provence (FR); Stéphanie LIMAGE, La Bouilladisse (FR); Alexandre KAUFFMANN, Marseille (FR); Virginie EL QACEMI, Roquevaire (FR); Louis-Dominique KAUFFMANN, Aix-en-Provence (FR)

(21) Appl. No.: 17/757,030

(22) PCT Filed: Nov. 19, 2020
(86) PCT No.: PCT/EP2020/082643

§ 371 Date: Jun. 8, 2022

(30) Foreign Application Priority Data
Dec. 11, 2019 (FR) FR1914183

(51) Int. Cl. C09D 11/52; C09D 11/033; C09D 11/037; H01L 31/0747; C08K 3/08; C08K 3/40

(52) U.S. Cl. CPC C09D 11/52; C09D 11/033; C09D 11/037; H01L 31/0747; C08K 3/08; C08K 3/40; B82Y 30/00

(57) ABSTRACT

The present invention relates to formulations of ink based on nanoparticles of silver and of metal oxides. In particular, the present invention relates to formulations of ink based on nanoparticles of silver and of metal oxides, said inks being stable, having improved conductivity and making it possible to advantageously form electrodes and/or conductive tracks that are particularly suitable for photovoltaic cells, for example on a silicon and/or glass substrate.

The present invention relates to formulations of ink based on nanoparticles of silver and of metal oxides. In particular, the present invention relates to formulations of ink based on nanoparticles of silver and of metal oxides, said inks being stable, having improved conductivity and making it possible to advantageously form electrodes and/or conductive tracks that are particularly suitable for photovoltaic cells, for example on a silicon and/or glass substrate.

The use of conductive pastes to form metal contacts on the surface of substrates such as silicon is well known. Such substrates can be used in photovoltaic cells (or solar cells) which convert solar energy into electrical energy. Crystalline silicon solar cells can be covered with an antireflection coating to promote the adsorption of light, which theoretically increases the efficiency of the cell while generating another problem since this antireflection coating also acts as an insulator; in general, the solar cells are therefore covered with this antireflection coating before applying conductive paste. Various types of antireflection coating can be used but in principle they contain silicon nitride and/or titanium oxide and/or silicon oxide.

To form the metal contacts, conductive tracks are therefore printed on a substrate which is then fired at a high temperature which is nevertheless lower than the melting point of silver and the eutectic point of silver and silicon. If the solar cell is covered with an antireflection coating before applying the conductive track, in order to be efficient, this conductive track must penetrate into the antireflection coating to form the necessary metal contacts with the substrate. During heating, however, some constituents of the conductive track and/or of the antireflection coating must be prevented from excessively contaminating the substrate since this would degrade the performance of the solar cell.

All these aspects must be carefully controlled to obtain good solar cell efficiency.

Consequently, there is a need for a composition that is easy to print, in order to form conductive tracks having the necessary ohmic contacts with the substrate of the solar cell without degrading the performance while taking into account, if necessary, the presence of the intermediate antireflection layer.

More particularly, the present invention relates to the field of inks based on conductive nanoparticles adapted for screen printing and/or coating.

The inks based on conductive nanoparticles according to the present invention can be printed on all types of support. We may mention, for example, the following supports:

polymers and polymer derivatives, composite materials, organic materials, inorganic materials and, in particular, silicon, glass and/or the intermediate antireflection layer as defined and described below.

The inks based on conductive nanoparticles according to the present invention offer numerous advantages, including the following given as non-limiting examples:
improved annealing (homogeneous deposit);
no bubbles/froth generated during printing;
improved dwell time (for example, the ink does not dry on the mask);
greater stability over time than the current inks;
non-toxic solvents and nanoparticles;
intrinsic properties of the nanoparticles preserved; and, in particular,
improved conductivity at annealing temperatures generally between 150° C. and 300° C.

The present invention also relates to an improved method for preparing said inks; lastly, the present invention also relates to the use of said inks in the field of screen printing and/or coating.

In view of the literature published in recent years, conductive colloidal nanocrystals have received a great deal of attention due to their new optoelectronic, photovoltaic and catalytic properties. This makes them particularly interesting for future applications in the fields of nanoelectronics, solar cells, sensors and biomedical.

The development of conductive nanoparticles leads to new implementations and opens the way to numerous new applications. Nanoparticles have a very large surface area to volume ratio and substituting their surface by surfactants leads to changes in certain properties, in particular optical, and the possibility of dispersing them.

In some cases, their small dimensions can produce quantum confinement effects. The term nanoparticles is used when at least one of the dimensions of the particle is less than or equal to 250 nm. Nanoparticles can be beads (from 1 to 250 nm), rods (L<200 to 300 nm), wires (a few hundred nanometers or even a few microns), discs, stars, pyramids, tetrapods, cubes or crystals when they do not have a predefined shape.

Several processes have been developed to synthesise conductive nanoparticles. We may mention, as non-exhaustive examples:
physical processes:
chemical vapour deposition (CVD) when a substrate is exposed to volatile chemical precursors which react or decompose on its surface. This process generally results in the formation of nanoparticles whose morphology depends on the conditions used;
thermal evaporation;
molecular beam epitaxy when the atoms that will form the nanoparticles are bombarded at high speed on the substrate (to which they will fix), in the form of a gas flow;
chemical or physico-chemical processes:
microemulsion;
laser pulse in solution, when a solution containing a precursor is irradiated by a laser beam. The nanoparticles form in the solution along the light beam;
Synthesis by microwave irradiation;
Oriented synthesis assisted by surfactants;
Ultrasonic synthesis;
Electrochemical synthesis;
Organometallic synthesis;
Synthesis in alcoholic medium.

Physical syntheses consume more raw materials with significant losses. They generally require time and high temperatures which make them unattractive to move to production on industrial scale. This makes them unsuitable for certain substrates, for example flexible substrates. In addition, the syntheses are carried out directly on the substrates in frames of small dimensions. These production methods are relatively rigid and cannot be used on large substrates; they may however be perfectly suitable for the production of silver nanoparticles used in the ink formulations according to the present invention.

Chemical syntheses have many advantages. The first is being able to work in solution, the conductive nanoparticles thus obtained are already dispersed in a solvent which simplifies their storage and use. In most cases, the nanoparticles are not fixed to a substrate at the end of the synthesis, which offers a wider range of possibilities regarding their use. This opens the way to the use of substrates of different sizes and types. These methods also allow better control over the raw materials used and limit losses. Correct adjustment of the synthesis parameters results in good control over the synthesis and growth kinetics of the conductive nanoparticles. This ensures good reproducibility between batches as well as good control over the final morphology of the nanoparticles. The ability to quickly produce large quantities of nanoparticles by chemical pathway while guaranteeing a certain flexibility regarding the product makes it possible to consider production on industrial scale. Obtaining dispersed conductive nanoparticles opens up numerous perspectives for their customisation. It is thus possible to adjust the nature of the stabilisers present on the surface of the nanoparticles depending on the targeted application. There are in fact several wet deposition methods. In each case, special attention must be paid to the physical properties of the ink such as the surface tension and the viscosity. The additives used when formulating the nanoparticle-based ink make it possible to closely respect the requirements of the deposition method. However, the surface ligands will also affect these parameters and must therefore be chosen extremely carefully. It is therefore important to have an overview of the ink to combine all the constituents—nanoparticles, solvent, ligands and additives—and obtain a product compatible with the targeted applications.

Ink

The present invention aims to overcome one or more disadvantages of the prior art by providing this ink adapted to the field of screen printing and/or coating, said ink comprising:

1. at least 30% by weight, preferably at least 40% by weight of silver nanoparticles, and preferably, less than 75% by weight of silver nanoparticles,
2. at least 0.1% by weight, preferably at least 0.2% by weight of metal oxides, and, preferably, less than 5% by weight, even less than 2% by weight of metal oxides, the metal oxides being selected from glass frits of size less than one micron and of composition comprising more than 50% by weight of silicon oxide,
3. at least 10% by weight, preferably at least 15% by weight of monohydric alcohol of boiling point greater than 150° C., and, preferably, less than 50% by weight, even less than 40% by weight of said alcohol,
4. at least 2% by weight, preferably at least 4% by weight of polyol and/or polyol ether, and, preferably, less than 20% by weight, even less than 15% by weight of polyol and/or polyol ether, and
5. optionally, one or more of the following compounds:
a. a cellulose compound as rheology modifier,
b. metal microparticles of silver and/or copper and/or nickel, and/or
c. a dispersing agent,
the sum of these optional compounds representing less than 30% by weight of the ink, and
said ink being characterised in that the sum of the above-mentioned compounds represents at least 90% by weight of the ink, preferably at least 95% by weight of the ink, for example at least 99% by weight of the ink.

Silver Nanoparticles

According to one embodiment of the present invention, the size of the silver nanoparticles of the ink claimed is between 1 and 250 nm, preferably between 10 and 250 nm, more preferably between 30 and 150 nm.

The distribution of the sizes of the silver nanoparticles as indicated in the present invention can be measured using any suitable method. For example, it can be advantageously measured using the following method: use of a Malvern Nanosizer S type device which has the following characteristics:

Dynamic light scattering (DLS) measurement method:
Tank type: optical glass
Material: Ag
Refractive index of the nanoparticles: 0.54
Absorption: 0.001
Dispersing agent: Cyclooctane
Temperature: 20° C.
Viscosity: 2.133
Refractive index of the dispersing agent: 1.458
General Options: Mark-Houwink parameters
Analysis Model: General purpose
Equilibration: 120 s
Number of measurements: 4

D50 is the diameter for which 50% of the silver nanoparticles by number are smaller. This value is considered as representative of the average size of the grains.

According to an alternative embodiment of the present invention, the silver nanoparticles are spheroidal and/or spherical. For the present invention and the claims which follow, the term “spheroidal” means that the shape resembles that of a sphere but is not perfectly round (“quasi-spherical”), for example an ellipsoidal shape. The shape and size of the nanoparticles may be advantageously identified by means of photographs taken by microscope, in particular using a device such as a transmission electron microscope (TEM) in compliance with the indications described below. The measurements are taken using a device such as a transmission electron microscope (TEM) manufactured by Thermofisher Scientific having the following characteristics:

TEM-BF (Bright Field) images are taken at 300 kV,

With a 50 μm objective lens for small magnifications and no objective lens for high resolution,

The dimensional measurements are taken on the TEM images using Digital Micrograph software, and

A mean is calculated on a number of particles representative of the majority of the particles, for example 20 particles, in order to determine a mean area, a mean perimeter and/or a mean diameter of the nanoparticles.

Thus, according to this alternative embodiment of the present invention, the nanoparticles are spheroidal and are preferably characterised using this TEM identification by a mean nanoparticle area of between 1 and 20 nm², preferably between 5 and 15 nm², and/or by a mean nanoparticle perimeter of between 3 and 20 nm, preferably between 5 and 15 nm, and/or a mean nanoparticle diameter of between 0.5 and 7 nm, de preferably between 1 et 5 nm.

According to an alternative embodiment of the present invention, the silver nanoparticles have the shape of beads, rods (of length L<200 to 300 nm), wires (of length L of a few hundred nanometres, even a few microns), cubes, plates or crystals when they do not have a predefined shape.

According to a special embodiment of the present invention, the silver nanoparticles have previously been synthesised by physical or chemical synthesis. Any physical or chemical synthesis can be used in the framework of the present invention. In a special embodiment of the present invention, the silver nanoparticles are obtained by chemical synthesis which uses an organic or inorganic silver salt as silver precursor. As non-limiting examples, we may mention silver acetate, silver nitrate, silver carbonate, silver phosphate, silver trifluorate, silver chloride, silver perchlorate, alone or in a mixture. According to an alternative of the present invention, the precursor is silver nitrate and/or silver acetate.

According to a special embodiment of the present invention, the silver nanoparticles are synthesised by chemical synthesis, by reducing the silver precursor using a reducing agent in the presence of a dispersing agent; this reduction can be carried out with or without a solvent.

Thus, the nanoparticles which are used according to the present invention are characterised by D50 values which are preferably between 1 and 250 nm irrespective of their synthesis method (physical or chemical); they are also preferably characterised by a monodisperse (homogeneous) distribution with no aggregates. D50 values between 30 and 150 nm for spheroidal silver nanoparticles can also be advantageously used.

The silver nanoparticle content as indicated in the present invention can be measured using any suitable method. For example, it can be advantageously measured using the following method:
Thermogravimetric analysis
Device: TGA Q50 manufactured by TA Instrument
Crucible: Alumina
Method: ramp
Measurement range: from ambient temperature to 600° C.
Rate of temperature increase: 10° C./min.

Metal Oxides

The inks according to the present invention therefore comprise metal oxides which are selected from glass frits of size less than one micron and of composition comprising more than 50% by weight of silicon oxide.

In one embodiment, the glass frit used in the conductive ink according to the present invention comprises more than 50% by weight of SiO₂, for example more than 75% by weight of SiO₂.

Other metal oxides may also be present in the frits, for example bismuth oxide, aluminium oxide, zinc oxide and boron oxide; an example of glass frit composition that can be advantageously used in the framework of the present invention comprises a mixture of SiO₂, Bi₂O₃, Al₂O₃ and ZnO which represents at least 75% by weight, preferably at least 90% by weight, for example 99% by weight of the glass frit composition.

The glass frit compositions according to the present invention may also tolerate the presence of other compounds such as for example Bi₂O₃, ZnO, Al₂O₃, Ag₂O, Sb₂O₃, GeO₂, In₂O₃, P₂O₅, V₂O₅, Nb₂O₅ and Ta₂O₅; and/or alkali metal oxides and/or alkaline earth metal oxides such as Na₂O, Li₂O and/or K₂O and BaO, CaO, MgO and/or SrO, respectively.

In a specific embodiment according to the present invention, the glass frit composition contains no lead or boron added intentionally; in such embodiments, the term “no lead and/or boron added intentionally” means a glass frit having a quantity of lead less than about 1000 ppm and/or a quantity of boron less than about 1000 ppm.

The glass frit content as indicated in the present invention can be measured using any suitable method. For example, the same method as that used for the silver nanoparticles will be used. According to a special embodiment of the present invention, the total frit content in the ink is between 0.1% and 5% by weight, preferably between 0.2% and 2% by weight relative to the ink.

The size of the glass frits and therefore of the metal oxides as indicated in the present invention can be measured using any suitable method. For example, the same method as that used for the silver nanoparticles will be used. According to a special embodiment of the present invention, the size of the glass frits and therefore of the metal oxides composing them will be advantageously between 5 and 250 nm. D50 values between 5 and 50 nm for spheroidal particles can be advantageously used. For example, we may mention the use of a silica whose specific surface area is between 150 and 250 m²/g (BET). Glass frits (according to the TEM measurement described above) having a mean area of between 1 and 20 nm², preferably between 5 and 15 nm², and/or a mean perimeter of between 3 and 20 nm, preferably between 5 and 15 nm, and/or a mean diameter of between 0.5 and 7 nm, preferably between 1 and 5 nm, may also be advantageously used in the framework of the present invention.

Monohydric Alcohols of Boiling Point Greater than 150° C.

The inks according to the present invention therefore comprise monohydric alcohol of boiling point greater than 150° C.; for example 2,6-dimethyl-4-heptanol and/or terpene alcohol. The inks according to the present invention preferably comprise a terpene alcohol selected from menthol, nerol, cineol, lavandulol, myrcenol, terpineol (alpha-, beta-, gamma-terpineol, and/or terpinen-4-ol; preferably, alpha-terpineol), isoborneol, citronellol, linalol, borneol, geraniol, and/or a mixture of two or more of said alcohols.

Polyols and/or Polyol Ethers

The inks according to the present invention therefore comprise a polyol and/or a polyol ether. The polyol and/or polyol ether is preferably characterised by a boiling point of less than 260° C. We may mention for example the glycols (for example ethylene glycol, propylene glycol, diethylene glycol, trimethylene glycol, 1,3-butylene glycol, 1,2-butylene glycol, 2,3-butylene glycol, pentamethylene glycol, hexylene glycol, etc.), and/or the glycol ethers (for example the glycol mono- or di-ethers amongst which we may mention for example ethylene glycol propyl ether, ethylene glycol butyl ether, ethylene glycol phenyl ether, propylene glycol phenyl ether, diethylene glycol methyl ether, diethylene glycol ethyl ether, diethylene glycol propyl ether, diethylene glycol butyl ether (butyl carbitol), propylene glycol methyl ether, propylene glycol butyl ether, propylene glycol propyl ether, ethylene glycol dimethyl ether, ethylene glycol diethyl ether, ethylene glycol dibutyl ether, glymes, diethylene glycol diethyl ether, dibutylene glycol diethyl ether, diglymes, ethyl diglyme, butyl diglyme), and/or the glycol ether acetates (for example 2-butoxyethyl acetate, diethylene glycol monoethyl ether acetate, diethylene glycol butyl ether acetate, propylene glycol methyl ether acetate), and/or a mixture of two or more of the above-mentioned compounds.

Optional Cellulose Compounds as Rheology Modifier

The inks according to the present invention therefore optionally comprise a rheology modifier which is advantageously selected from the cellulose compounds. We may mention for example the alkyl celluloses, the hydroxyalkyl celluloses and the carboxyalkyl celluloses, preferably ethylcellulose.

According to one embodiment of the present invention, the ink claimed comprises the cellulose compound in a content greater than 0.5% by weight, for example greater than 1% by weight; however, its content in the ink will preferably be kept to less than 5% by weight, or even less than 2% by weight.

Metal Microparticles of Silver and/or Copper and/or Nickel

The inks according to the present invention therefore optionally comprise metal microparticles of silver, copper and/or nickel. These microparticles may have the shape of a sphere, a flake and/or of filaments, and have a size of preferably less than 15 μm, for example less than 10 μm, preferably less than 5 μm. Microparticles having (according to the TEM measurement described above) a mean area of between 1 and 25 μm², preferably between 5 and 15 μm², and/or a mean perimeter of between 3 and 20 μm, preferably between 5 and 15 μm, and/or a mean diameter of between 1 and 7 μm, preferably between 1 and 5 μm, may also be advantageously used in the framework of the present invention.

As an example, the metal microparticles may be composed of silver, or a copper-silver mixture, or a nickel-silver mixture. In particular, these microparticles may have a copper core and a silver shell, or a nickel core and a silver shell. For core/shell particles, the metal forming the core will represent for example between 85% and 95% by weight of the total composition of the microparticle.

According to one embodiment of the present invention, the ink claimed comprises these microparticles in a content greater than 5% by weight, for example greater than 10% by weight; however, their content in the ink will preferably be kept to less than 25 by weight, or even less than 20% by weight.

Dispersing Agents

The inks according to the present invention therefore optionally comprise dispersing agents, for example organic dispersing agents which preferably comprise at least one carbon atom. These organic dispersing agents may also comprise one or more non-metal heteroatoms such as a halogenated compound, nitrogen, oxygen, sulphur, silicon. We may mention for example the thiols and their derivatives, the amines and their derivatives (for example the aminoalcohols and the aminoalcohol ethers), the carboxylic acids and their carboxylate derivatives, and/or their mixtures.

According to one embodiment of the present invention, the ink claimed comprises these dispersing agents in a content greater than 0.1% by weight, for example greater than 0.5% by weight; however, their content in the ink will preferably be kept to less than 3% by weight, or even less than 2% by weight.

Other Compounds

Although this is not a preferred embodiment according to the present invention, the ink claimed may also tolerate the presence of other compounds in its formulation. Preferably however, their content will be limited to less than 10% by weight, for example less than 5% by weight, even less than 1% by weight of the ink. We may mention for example water, the monohydric alcohols and/or the antioxidant agents. The monohydric alcohol is preferably selected from the alcohols with linear or branched aliphatic radical, for example an alcohol having from 1 to 10 carbon atoms. We may mention for example methanol, ethanol, butanol, heptanol, dimethyl heptanol, 2,6-dimethyl-4-heptanol and/or a mixture of two or more of said alcohols. We may mention as examples of antioxidant agents:
ascorbic acid or vitamin C (E300), sodium ascorbate (E301), calcium ascorbate (E302), 5-6-1-diacetyl ascorbic acid (E303), 6-1-palmityl ascorbic acid (E304);
citric acid (E330), sodium citrate (E331), potassium citrate (E332) and calcium citrate (E333);
tartric acid (E334), sodium tartrate (E335), potassium tartrate (E336) and sodium and potassium tartrate (E337);
butylhydroxyanisol (E320) and butylhydroxytoluol (E321);
octyl gallate (E311) or dodecyl gallate (E312);
sodium lactate (E325), potassium lactate (E326) or calcium lactate (E327);
lecithins (E322);
natural tocopherols (E306), synthetic α-tocopherol (E307), synthetic γ-tocopherol (E308) and synthetic δ-tocopherol (E309), all the tocopherols forming vitamin E;
eugenol, thymol and/or cinnamaldehyde,
as well as a mixture of two or more of said antioxidant agents.

The ink viscosity measured at a shear rate of 40 s⁻¹ and at 20° C. according to the present invention is generally between 1000 and 100 000 mPa·s, preferably between 5000 and 50 000 mPa·s, for example between 10 000 and 40 000 mPa·s.

The viscosity can be measured using any suitable method. For example, it can be advantageously measured using the following method:
Device: Rheometer AR-G2 manufactured by TA Instrument
Conditioning time: Pre-shearing at 100 s⁻¹ for 3 minutes/equilibration for 1 minute
Test type: Shear stages

Stages: 40 s⁻¹, 100 s⁻¹ and 1000 s⁻¹
Stage duration: 5 minutes
Mode: linear
Measurement: every 10 seconds
Temperature: 20° C.
Curve reprocessing method: Newtonian
Reprocessed area: the entire curve

According to one embodiment of the present invention, the ink composition may also include other compounds, for example additives (for example, an additive of the silane family) intended to improve the resistance to various types of mechanical stress, for example the adhesion to numerous substrates.

Substrate

The inks based on conductive nanoparticles according to the present invention can be printed on all types of support. We may mention, for example, the following supports: polymers and polymer derivatives, composite materials, organic materials, inorganic materials and, in particular, silicon, glass, ITO glass, AZO glass, SiN glass and/or the intermediate antireflection layer as defined and described below.

The substrates may be advantageously used in solar cells or photovoltaic cells which convert solar energy into electrical energy when the photons of the sunlight excite the electrons on the semiconductors from the valence band to the conduction band. The electrons which migrate to the conduction band are collected by the metal contacts.

For example, a photovoltaic cell consists of a stack of layers with different functions: an active layer, composed of electron donor and acceptor materials, positive and negative electrodes, and additional layers (antireflection, greater doping, etc.) to improve the performance of the cell. In a traditional photovoltaic cell, the active cell is composed of mono- or multi-crystalline silicon onto which an antireflection layer based on silicon nitride SiN or hydrogenated silicon nitride SiNx:H is deposited. The electrodes are generally composed of aluminium on the rear and silver on the front.

This type of cell is manufactured according to the following steps: texturising the silicon layer by chemical engraving, then forming the donor/acceptor junction (diffusion of phosphorus then plasma engraving to open the junction and eliminate the short circuits). The antireflection layer is then deposited using the PECVD process. Lastly, metallisation of the cell consists in depositing by screen printing a solid aluminium layer on the rear and a silver grid on the front. The contacts are generally annealed by being placed in an oven with in particular a “firing” step at very high temperature, between 700° C. and 800° C.

In recent years, a new type of hybrid cell has been developed: heterojunction solar cells. These cells have numerous differences compared with the traditional cells described above. Firstly, the active layer consists of several crystalline and amorphous silicon layers with different doping concentrations. Secondly, the front and rear have two ITO layers. The metallisation is also different since it consists in depositing by screen printing a silver grid on the front and rear. Lastly, it is interesting to point out that during the manufacturing process, these cells do not undergo a firing step as described in the previous paragraph, but heat treatment not exceeding 250° C., which is why our claimed inks are perfectly suitable.

According to an alternative of the present invention, preparation of the nanoparticle-based ink according to the present invention is characterised by the following steps:

S1=Dispersing ethyl-cellulose in terpineol with mechanical stirring and heating;
S2=Dispersing the glass nano-frits in S1 with mechanical stirring and at ambient temperature;
S3=Dispersing the optional microparticles (silver and/or copper and/or nickel powder) in S2 with mechanical stirring and at ambient temperature;
S4=Adding in S2 or S3 the silver nanoparticles which are in butyl carbitol, with mechanical stirring and at ambient temperature.

The ink thus obtained can be used directly or diluted to obtain the required properties.

According to one or more embodiments, the conductive ink is printed on the surface of the substrate or on the intermediate antireflection layer (itself adhered to the substrate) by screen printing or coating. The assembly is advantageously heated to a temperature less than 250° C. to form the conductive lines. In one embodiment, as discussed above in the application, the thermal process allows the glass frit to melt and penetrate into the intermediate antireflection layer to come into contact with the substrate. In one or more embodiments, the conductive species form crystallites at the interface between the conductors and the substrate, which improves the electrical and ohmic contact between the conductors and the semiconductor substrate.

Thus, the present invention also relates to a use of an ink as claimed in screen printing or coating to form conductive lines when manufacturing heterojunction solar cells; this use of an ink is also advantageously characterised in that the formation of the conductive lines comprises heat treatment at a temperature less than 250° C.

It is therefore clear to those skilled in the art that other embodiments are possible with the present invention, in numerous other specific forms, without leaving the scope of the invention as claimed. Consequently, these embodiments must be considered as examples, which may be modified in the field defined by the scope of the attached claims. The present invention and its advantages will now be illustrated using the formulation provided below. The ink formulation was prepared according to the preferred embodiment described above in the description.

An ink formulation was prepared according to the present invention, comprising:
55% by weight of silver nanoparticles with a D50 of 130 nm,
20% by weight of silver microparticles having the shape of flakes with a D50 of 2.3 μm,
5% by weight of butyl carbitol
17.6% by weight of terpineol
1.4% by weight of ethyl cellulose
1% by weight of SiO₂ with a primary D50 of 12 nm

This formulation has a viscosity of 30 000 mPa·s measured at a shear rate of 40 s⁻¹. Depositing this ink by coating (with a wet thickness of 24 μm) on a silicon plate covered with ITO heated to 150° C. for 10 minutes then 200° C. for 30 minutes gives a resistance per square of 6 mohm/sq and excellent adhesion (5B according to standard ASTM D3359).

1. Ink comprising:
1. at least 30% by weight of silver nanoparticles,
2. at least 0.1% by weight of metal oxides, the metal oxides being selected from glass frits of size less than one micron and of composition comprising more than 50% by weight of silicon oxide,
3. at least 10% by weight of monohydric alcohol of boiling point greater than 150° C.,
4. at least 2% by weight of polyol and/or polyol ether, and
5. optionally, one or more of the following compounds:
a. a cellulose compound as rheology modifier,
b. metal microparticles of silver and/or copper and/or nickel, and/or
c. a dispersing agent,
the sum of these optional compounds representing less than 30% by weight of the ink, and said ink being characterised in that the sum of the above-mentioned compounds represents at least 90% by weight of the ink.

2. Ink according to claim 1, comprising:
1. at least 40% by weight of silver nanoparticles,
2. at least 0.2% by weight of metal oxides,
3. at least 15% by weight of monohydric alcohol of boiling point greater than 150° C.,
4. at least 4% by weight of polyol and or polyol ether.

3. Ink according to claim 1, comprising:
1. less than 75% by weight of silver nanoparticles,
2. less than 5% by weight of metal oxides,
3. less than 50% by weight of monohydric alcohol of boiling point greater than 150° C., and
4. less than 20% by weight of polyol and/or polyol ether.

4. Ink according to claim 3, comprising:
2. less than 2% by weight of metal oxides,
3. less than 40% by weight of monohydric alcohol of boiling point greater than 150° C., and
4. less than 15% by weight of polyol and/or polyol ether.

5. Ink according to claim 1, characterised in that the metal microparticles of silver and/or copper and/or nickel are present in a content greater than 5% by weight and less than 25% by weight of the ink, for example in a content greater than 10% by weight and less than 20% by weight of the ink.

6. Ink according to claim 1, characterised in that the cellulose compound is present in a content greater than 0.5% by weight and less than 5% by weight of the ink, for example in a content greater than 1% by weight and less than 2% by weight of the ink.

7. Ink according to claim 1, characterised in that the dispersing agent is present in a content greater than 0.1% by weight and less than 3% by weight of the ink, for example in a content greater than 0.5% by weight and less than 2% by weight of the ink.

8. Ink according to claim 1, characterised in that the monohydric alcohol of boiling point greater than 150° C. is 2,6-dimethyl-4-heptanol and/or terpene alcohol.

9. Ink according to claim 8, characterised in that the terpene alcohol is terpineol.

10. Ink according to claim 1, characterised in that the sum of the above-mentioned compounds represents at least 95% by weight of the ink, for example at least 99% by weight of the ink.

11. Ink according to claim 1, characterised in that the ink viscosity measured at a shear rate of 40 s⁻¹ and at 20° C. is between 1000 and 100 000 mPa·s, preferably between 5000 and 50 000 mPa·s, for example between 10 000 and 40 000 mPa·s.

12. Use of an ink according to claim 1, in screen printing or coating to form conductive lines when manufacturing heterojunction solar cells.

13. Use of an ink according to claim 12, characterised in that the formation of the conductive lines comprises heat treatment at a temperature less than 250° C.
